(19) United States
(12) Patent Application Publication
(10) Pub. No.: US 2008/0165679 A1
(43) Pub. Date: Jul. 10, 2008

(54) Method to mitigate fraudulent usage of QoS from mobile terminals using uplink packet marking

(75) Inventors: Nicholas W. Anderson, Bristol (GB); Haris Zisimopoulos, Reading (GB)

Correspondence Address: MORRISON & FOERSTER LLP, 425 MARKET STREET, SAN FRANCISCO, CA, 94105-2482, US

(73) Assignee: IPWireless, Inc., San Bruno, CA (US)

(21) Appl. No.: 11/652,224

(22) Filed: Jan. 10, 2007

(51) Int. Cl. G01R 31/08

(52) U.S. Cl. 370/230

(57) ABSTRACT

A method is provided for mapping between an uplink traffic characteristic and a transmission prioritization level to prevent fraudulent access to priority flows at a centralized point in a network. According to certain embodiments, an Access Gateway (AGW) receives at least one network filter parameter from a network element, which indicates expected priorities. The User Equipment (UE) transmits a message over a traffic flow to an Access Point (AP), including an indicator of the actual priority at the AP. The message is forwarded to an AGW. The actual priority is determined at the user equipment according to a message characteristic and an uplink filter parameter, which is associated with the traffic flow that was used for transmission. Access to priority flows is determined based on comparing the expected priority and the actual priority of the message.

### BACKGROUND OF THE INVENTION

In mobile networks, relevant network resources need to be provided to different service flows in order to meet their quality of service (QoS) requirements. This is required to achieve a good user experience for the different service types, and also to optimize use of the available network resources. Undue deterioration to other users or services is avoided by not “over-provisioning” some services with network resources. The network logic allocates resources to different terminals and service flows depending on a number of factors, including: service flow requirements, operator's policies, and user profile and network resource availability at the time of the request. Radio conditions experienced by the users may also affect the quantity of available resources. These factors are examples that may determine the QoS treatment a certain service flow receives when transported over a mobile network. These factors are referred to as “QoS policies” hereinafter.

In the uplink, provisioning of differentiated QoS between services for the user equipment (UE) includes providing traffic filters, which indicate the traffic flow description and map the traffic onto radio bearers according to proper priority. The traffic filters are configured and controlled by a policy server located in the network. Nevertheless, the UE should not be trusted by the network to always perform the correct mapping and follow the rules provided by the network. Some fraudulent UEs may attempt to inappropriately map certain low priority traffic types to high priority bearers to achieve better QoS. If such loop-holes were exploited by fraudulent users, then users on the network exhibiting correct behavior may experience a poor level of service due to the fraudulent users occupying a disproportionate (i.e., excessive) fraction of the total available network and radio resources.

Therefore, a method is desired for determining proper access to priority traffic flows.

### BRIEF SUMMARY OF THE INVENTION

Embodiments of the invention provide a configured mapping between an uplink traffic characteristic and a transmission prioritization level to prevent fraudulent access to priority flows at a centralized point in a network. According to certain embodiments, an Access Gateway (AGW) receives at least one network filter parameter from a network element, which indicates expected priorities. The User Equipment (UE) transmits a message over a traffic flow to an Access Point (AP) and the message is forwarded to an AGW. The message includes an indicator of the actual priority at the AP. The actual priority is determined at the user equipment according to a message characteristic and an uplink filter parameter, which is associated with the traffic flow that was used for transmission. Message characteristics may include, but are not limited to, source IP address, source port, destination IP address, destination port, and protocol identification. Access to priority flows is determined based on comparing the expected priority and the actual priority of the message.

In some embodiments, when the actual priority level does not match the expected transmission priority level, passage of the data is affected by blocking further transmission of user data packets to another network element. In other embodiments, when the actual priority level does not match the expected transmission priority level, passage of the data is affected by delaying further onward transmission of user data packets to another network element. Furthermore, in other embodiments, when the actual priority level does not match the expected transmission priority level, passage of the data may be affected by disconnecting the UE.

### BRIEF DESCRIPTION OF THE DRAWINGS

FIG. 1 illustrates a cellular communication system according to embodiments of the invention;

FIG. 2 illustrates mapping of traffic flows to appropriate radio bearers in a user equipment using uplink filters according to embodiments of the invention;

FIG. 3 illustrates mobile network architecture in post-3G systems according to embodiments of the invention;

FIG. 4 illustrates packet marking based on the radio bearer priority according to embodiments of the invention;

FIG. 5 illustrates a flowchart of processing steps in the access gateway (AGW) according to embodiments of the invention;

FIG. 6 illustrates blocking of traffic inappropriately sent over a high priority bearer according to embodiments of the invention;

FIG. 7 illustrates filter delivery using access specific protocols according to embodiments of the invention;

FIG. 8 illustrates uplink filter deliver using SIP SUBSCRIBE/NOTIFY according to embodiments of the invention;

FIG. 9 illustrates uplink filter delivery to the UE using SIP SUBSCRIBE/NOTIFY mechanisms according to embodiments of the invention; and

FIG. 10 illustrates a computer system that may be employed to implement embodiments of the invention

### DETAILED DESCRIPTION OF THE INVENTION

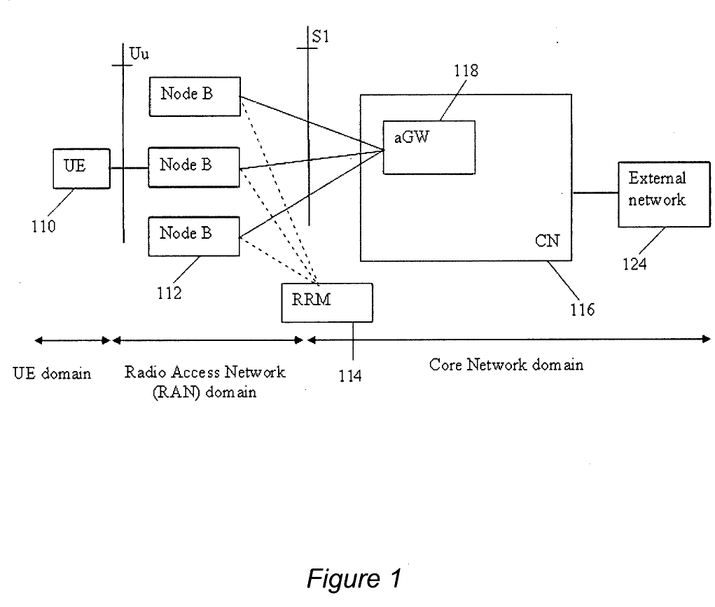

FIG. 1 illustrates an example of a cellular communication system according to embodiments of the invention. The network includes a User Equipment (UE) domain, a radio access network (RAN) domain, and a core network (CN) domain. The user equipment domain includes UE 110 that communicates with at least one base station 112 in the RAN domain via a wireless interface. The RAN domain may also include a network controller (e.g., radio network controller) (not shown), such as that used in UMTS systems. Alternatively, such functionality may be distributed between the Node Bs and the AGW or other controller in the core network. FIG. 1 also illustrates an optional radio resource manager (RRM) 114. As described below, the RRM may perform functions otherwise performed by the Node Bs or AGW in some embodiments.

The core network (CN) 116 includes, in this example, an access gateway (AGW) 118. The core network is coupled to an external network 124. Further details may be found in the 3GPP System Architecture Evolution (SAE) technical specifications, such as TR 23 882 “3rd Generation Partnership Project; Technical Specification Group Services and System Aspects; 3GPP system architecture evolution (SAE): Report on technical options and conclusions,” published by the 3GPP, which are incorporated by reference herein.

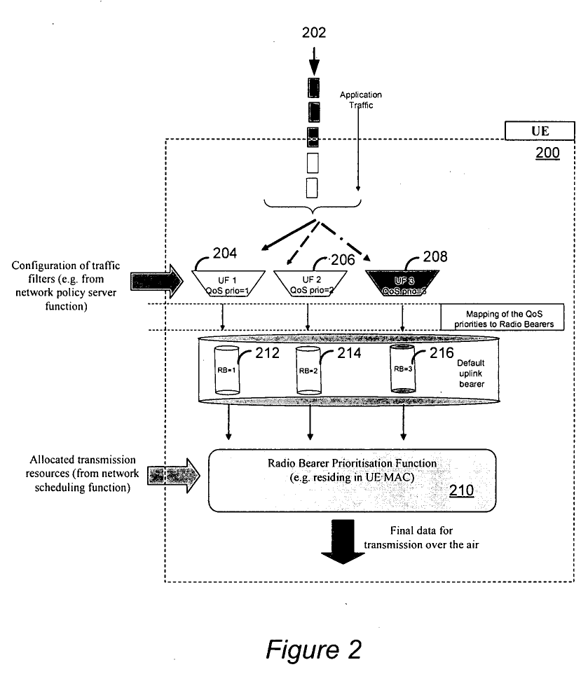

FIG. 2 depicts an embodiment of a UE in which an uplink user traffic stream 202 (aggregated across multiple applications) is split by user traffic filters (UF) 204, 206, 208 into several flows prior to transmission, each flow carrying traffic that conforms to the traffic filter rules configured for that flow. A QoS profile, including a set of parameters, is associated with each flow. When a user is granted transmission resources, typically by a scheduler residing in the network, a prioritization function 210 inside the UE 200 decides which of the contending data flows may be serviced, and the relative volumes of data that may be taken from each of the flows and mapped to the allocated transmission resources. In embodiments of the invention, this prioritization function 210 may reside within the Medium Access Control (MAC) layer of the UE's protocol stack. The QoS profile (e.g., a parameter), associated with each flow is known to the prioritization function 210 and may be used to assist the prioritization function 210 in deciding how much data to take from each of the flows when building the transmission data block to send on the allocated resources.

In general, the radio channels that are used to carry the traffic flows with different priorities may also be known as “radio bearers”. Furthermore, one or more radio bearers may be associated with one “access bearer”, which is a particular tunnel that carries the traffic of the RAN to the AGW 118 in the CN 116. The access bearer typically carries traffic of the same generic type or class (e.g., best-effort web traffic, guaranteed bit-rate voice or streaming video). Multiple access bearers may be configured if these multiple traffic classes exist simultaneously. The provisioning of multiple radio bearers mapped to the same access bearer allows for differing QoS to be delivered for specific sub-categories of traffic within the access bearer (e.g., to distinguish between two or more different applications that both belong to the same web traffic class/access bearer). In the example illustrated in FIG. 2, three radio bearers 212, 214, and 216 are associated with a single access bearer. Although it should be understood that further access bearers, each associated with one or more radio bearers, may also exist.

To ensure fair distribution of resources among users and/or their services, it is advantageous that the network is able to police the UEs to monitor if the imposed rules are being followed and if QoS policies are being misused. Policing in fixed IP networks usually happens in the edge routers that are normally referred to as “boundary nodes” (e.g., as in Internet Engineering Task Force's (IETF) [RFC2475], which is incorporated by reference herein). Generally, in network architectures, there is a limited number of boundary nodes that perform the QoS policing due to the complexity required to inspect the traffic packet-by-packet and apply the rules. In that case, the boundary nodes are sometimes configured as network gateways, and the network traffic ingress and egress to/from the network via these fixed points. This allows for easy distribution of the rules. Furthermore, the policing function may be restricted to a small number of nodes, thus facilitating simpler network management.

In next generation mobile networks, it is desired that the number of network nodes are reduced to limit the network delay and system complexity. The network for this sort of architecture has effectively two nodes: the wireless Access Point (AP) and the system's Access Gateway (AGW). The AP and the AGW are usually connected with a tunneling protocol (e.g. GTP [3GPP TS 29.060] in GPRS, which is incorporated by reference herein).

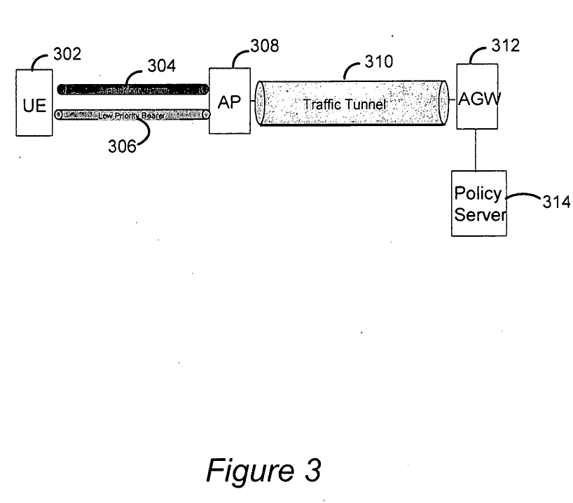

FIG. 3 depicts a network architecture described above. In addition, FIG. 3 illustrates the existence of two radio bearers of differing priority between a UE 302 and a network wireless AP 308—a high priority bearer 304, and a low priority bearer 306. User traffic for uplink transfer is mapped by the UE 302 onto the radio bearers 304 or 306 according to the filter rules established by the policy server 314, as previously discussed above. The data received at the AP 308 from each of the flows and from each user is multiplexed onto a traffic tunnel 310 that exists between the AP 308 and AGW 312. The use of a single tunnel 310 (as opposed to multiple parallel tunnels) may be preferred in certain embodiments as it may provide for simpler management and reconfiguration of the network, especially as the mobile user moves between APs, and possibly AGWs. Generally, multiple tunnels may exist, although, ideally, the number of tunnels is kept to a minimum.

In certain embodiments of the network architecture, the user plane traffic ingress/egress points to the access network are the Wireless Access Points (e.g. NodeB in UMTS) in the uplink and the network's gateway node (e.g. GGSN in GPRS) in the downlink. To police the uplink traffic transmitted by the UEs in embodiments of this network architecture, the policy rules may need to be distributed to the APs. However, the APs are geographically distributed, and as the UE moves and changes its point of attachment (PoA) to a new AP, the old AP sends to the new AP the policy rules that apply for any ongoing sessions the UE might have in effect. In the case that the mobility factor is large (e.g., the UE is required to change its PoA often), a large number of signaling overhead may be generated to transport the rules from AP to AP. The handover performance in terms of delay may be affected since the APs need to process the rules and filter the traffic before forwarding it to the next node.

Therefore, according to embodiments of the invention, the need to distribute the filters to the AP to perform policing of the uplink traffic may be avoided if the AP 308 marks the uplink packets with an appropriate outer header field in the tunneling protocol. The marked header indicates to the AGW 312 whether or not the packets were transported over the air using the high priority bearer 304 or low priority bearer 306. This may allow the AGW 312 to apply the rules received by the Policy Server 314, and to permit access only to the packets with their outer header marked with a priority that matches that of the filters configured in the AGW 312 by the Policy Server 314. Thus, when AGW 312 inspects the traffic received over the tunnel 310 from the AP 308, it may determine which traffic filter rule should have been applied and can subsequently check that the actual priority marking of the packet(s) matches the expected priority marking for the determined traffic filter. If there is a match, the traffic is allowed to flow and is forwarded accordingly. If there is a mismatch, the AGW 312 may decide to block or reduce the flow of that traffic. Other measures may also be taken if there is a mismatch, such as disconnecting the UE 302 from the network, for example.

This mechanism advantageously removes any benefit to a fraudulent user to intercept or change the uplink mapping filters in the UE since only appropriately mapped uplink traffic will egress the mobile network. Therefore, the fraudulent user will be unable to benefit from misuse of high priority radio bearers.

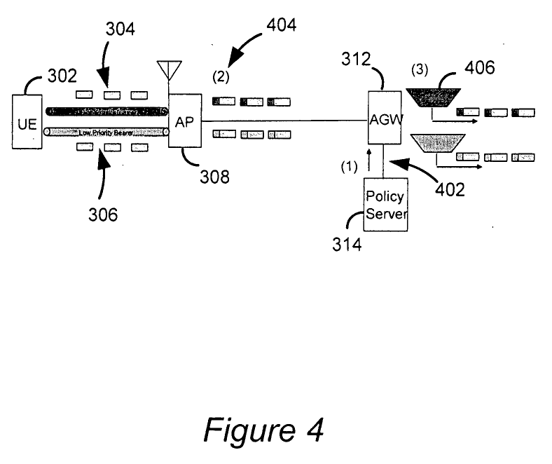

In FIG. 4, the Policy Server 314 provides the AGW 312 with the Uplink Traffic Filters that determine the different traffic flows and their applied QoS priority in step 402. The traffic filters may uniquely identify the different traffic flows and designate the proper priority. For example, the traffic filters may be based on the 5-tuple identifier (e.g., Source IP address, Source Port, Destination IP address, Destination Port, Protocol ID).

| | | | | | | QoS |
|---|---|---|---|---|---|---|
| FilterID | SrcAdd | SrcPort | DestAdd | DestPort | ProtoID | Prio |
| 1 | * | * | 192.168.1.1 | 80 | * | 1 |

The UE 302 begins sending uplink traffic, mapping the different traffic flows to radio high priority bearers 304 or low priority radio bearers 306. The AP 308, before forwarding the packets to the AGW 312, marks in an outer header the relative priority of the radio bearers used to transport the traffic over the air as in step 404. In some embodiments, for example in which the Internet Protocol (IP) is used, the priority of the transmitted message is indicated as a differentiated service “DiffServ” Codepoint (DSCP), which are a set of markings described by the Internet Engineering Taskforce (IETF) in [RFC2475], which is herein incorporated by reference.

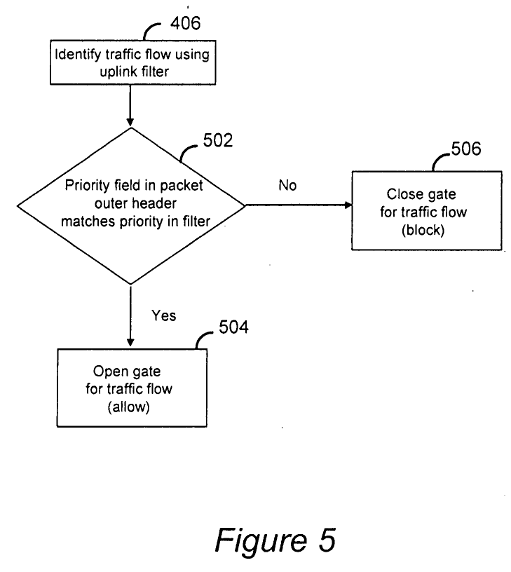

As illustrated in FIG. 4 and FIG. 5, the AGW 312 inspects the different traffic flows and identifies whether the QoS actual priority that is indicated in the outer header matches the expected priority provided with the filter by the Policy Server as in step 406. If the actual and expected priority match, the AGW 312 “opens the gate” for this flow and allows the packets to egress the network as in step 504. Otherwise, if the expected priority and actual priority do not match, the AGW 312 blocks the traffic as in step 506.

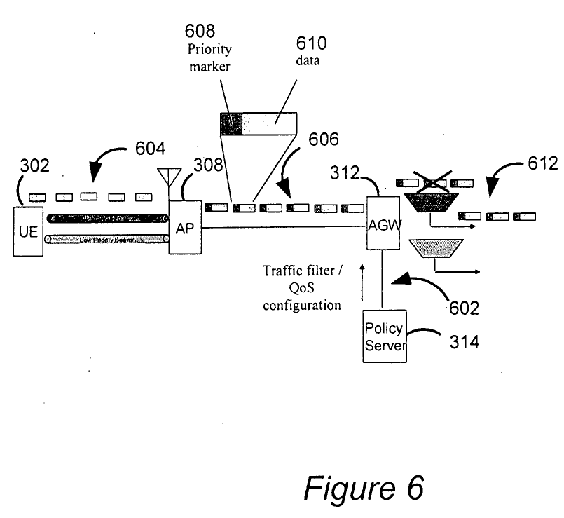

In FIG. 6, according to embodiments of the invention, an AGW blocks traffic that was inappropriately mapped to a high priority bearer using a packet marking indication. The policy server 314 provides the AGW 312 with traffic filters, which indicates the QoS configuration, as in step 602. The UE 302 begins sending uplink traffic, mapping it to the radio high priority bearers 304. The AP 308, before forwarding the packets to the AGW 312, marks in an outer header 608 the relative priority of the radio bearers used to transport the traffic over the air as in step 606. The AGW 312 inspects the different traffic flows and identifies whether the QoS actual priority that is indicated in the outer header 608 matches the expected priority in step 606 provided with the filter by the Policy Server as in step 602. The AGW 312 is not able to match the expected priority with the actual priority and blocks the inappropriately-mapped traffic over the high priority bearer as in step 612. Traffic appropriately mapped to the high priority bearer is allowed to pass.

In embodiments of the invention, the user equipment (UE) may be provided with traffic filters that will indicate the traffic flow description via a variety of protocols and mechanisms. The filters may map the traffic onto radio bearers with the required priority according to a message characteristic. The filters may also be configured and controlled by a policy server located in the network. For example, mechanisms and signaling protocols specific to the access network used (e.g., Non-Access Stratum (NAS) signaling or Radio Resource Control (RRC) for UMTS) may be used to control filter delivery. These mechanisms and protocols may suffice to deliver the filters in the case that the policy server controls only one access network, or when only one access network is in use by the UE.

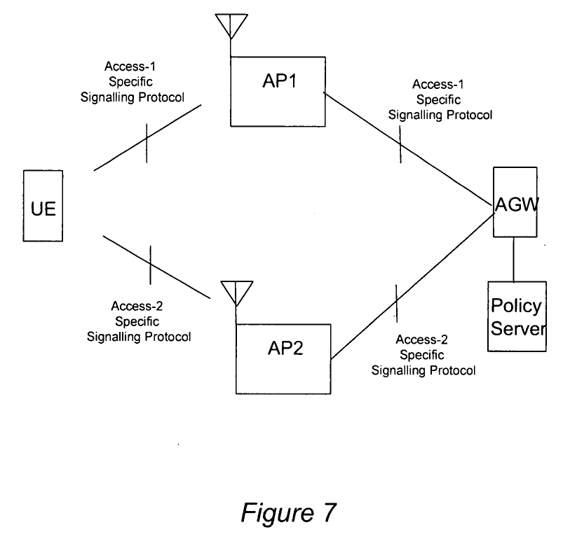

In some embodiments, the UE may be a multi-mode UE, and can connect and receive services across a number of access networks (e.g., UMTS, WLAN). Alternatively, in some embodiments, the policy server may preside over multiple access networks of different types. Signaling protocols that may be used between the AGW and the AP may differ depending on the access technology used. Therefore, the delivery of the filters to the UE may need to be provided with many different protocols. For this type of network, it is beneficial to deliver the filters directly to the UE in a manner irrespective to the access network type, to avoid the complexity of dealing with many different signaling protocols, as illustrated in FIG. 7.

An example of a protocol, which may be used for this purpose, is the Session Initiation Protocol (SIP). SIP has been defined by the Internet Engineering Taskforce (IETF), and is an application-layer control (signaling) protocol for creating, modifying, and terminating sessions with one or more participants. For example, these sessions include Internet telephone calls, multimedia distribution, and multimedia conferences. SIP has already been adopted by a large number of industry standards (e.g., 3GPP, 3GPP2, TISPAN, WiMax Forum) and is a fundamental component of the IP Multimedia System (IMS), which is a standardized Next Generation Networking (NGN) architecture for telecom operators that want to provide mobile and fixed multimedia services.

Additionally, an extension of SIP has been previously defined, which allows clients to subscribe and be notified when specific resources in a remote server change. This mechanism is commonly used for services, such as presence and terminal remote configuration because it allows remote servers to “push” specific content to the terminals. This particular mechanism can be used to deliver the UL filters to the UE in an “access agnostic” manner. For example, the UE may directly connect to the remote Policy Server and not rely on any particular access network at any particular time.

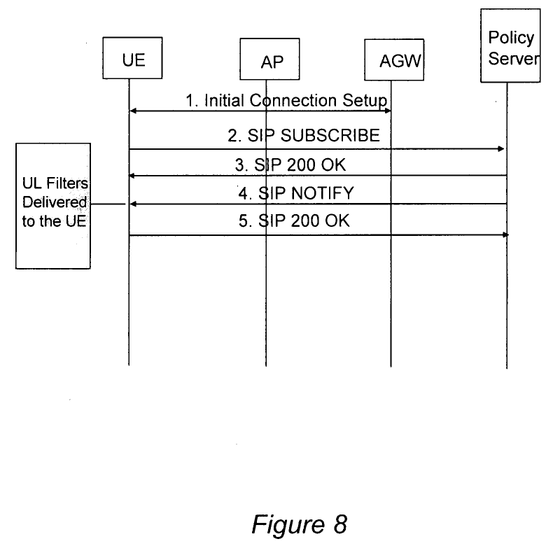

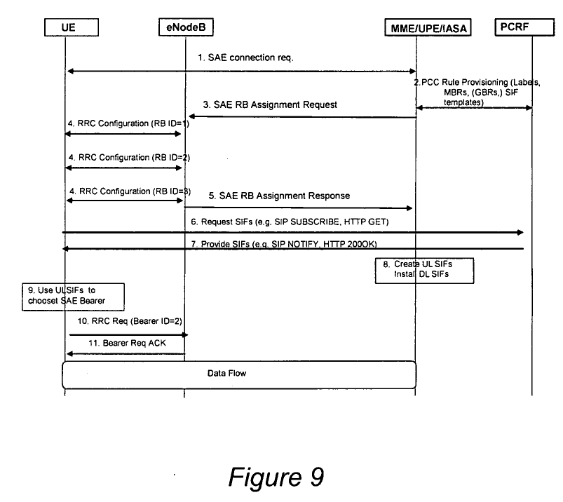

The establishment of the default SAE bearer is not associated with the delivery of the UL Filters to the UE. The UL filters are obtained by the UE using “higher layer” signaling (e.g., SIP SUBSCRIBE/NOTIFY) illustrated in FIG. 8 and FIG. 9. A possible advantage may be that with this mechanism, the QoS rules may be applied to different access network types (e.g., 3GPP/non-3GPP access technologies) given that the UL Filters are not delivered using 3GPP-specific signaling mechanisms.

In some embodiments according to the present invention, each access network type provides the appropriate mapping of the QoS priorities expressed in the filters to the radio technology. In the signaling flow of these embodiments, we assume that the access network used is 3GPP LTE.

While the invention has been described in terms of particular embodiments and illustrative figures, those of ordinary skill in the art will recognize that the invention is not limited to the embodiments or figures described. Although embodiments of the present invention are described, in some instances, using UMTS terminology, those skilled in the art will recognize that such terms are also used in a generic sense herein, and that the present invention is not limited to such systems.

Those skilled in the art will recognize that the operations of the various embodiments may be implemented using hardware, software, firmware, or combinations thereof, as appropriate. For example, some processes can be carried out using processors or other digital circuitry under the control of software, firmware, or hard-wired logic. (The term “logic” herein refers to fixed hardware, programmable logic and/or an appropriate combination thereof, as would be recognized by one skilled in the art to carry out the recited functions.) Software and firmware can be stored on computer-readable media. Some other processes can be implemented using analog circuitry, as is well known to one of ordinary skill in the art. Additionally, memory or other storage, as well as communication components, may be employed in embodiments of the invention.

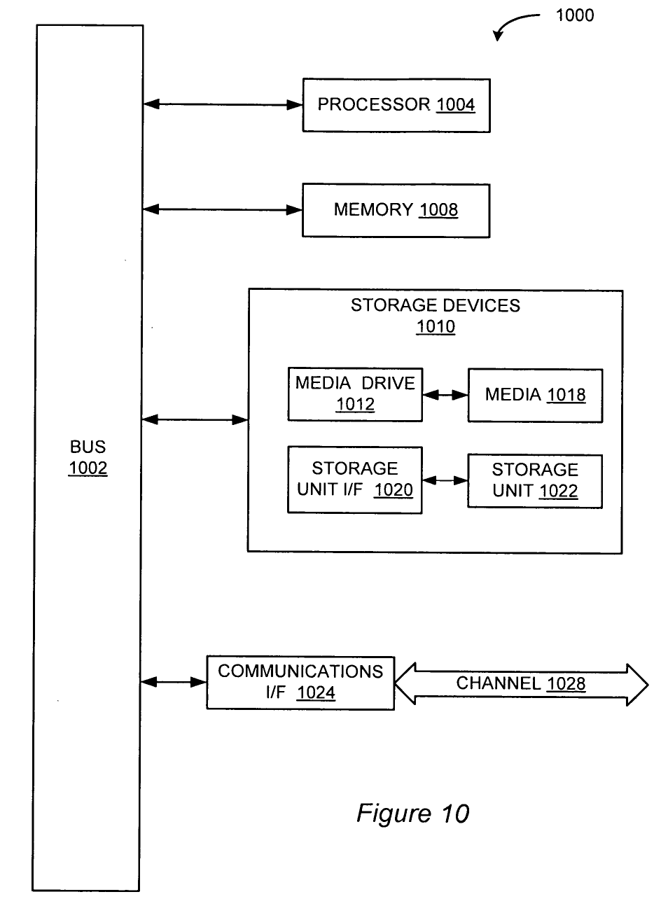

FIG. 10 illustrates a typical computing system 1000 that may be employed to implement processing functionality in embodiments of the invention. Computing systems of this type may be used in the radio controllers, the base stations, and the UEs, for example. Those skilled in the relevant art will also recognize how to implement the invention using other computer systems or architectures. Computing system 1000 may represent, for example, a desktop, laptop or notebook computer, hand-held computing device (PDA, cell phone, palmtop, etc.), mainframe, server, client, or any other type of special or general purpose computing device as may be desirable or appropriate for a given application or environment. Computing system 1000 can include one or more processors, such as a processor 1004. Processor 1004 can be implemented using a general or special purpose processing engine such as, for example, a microprocessor, microcontroller or other control logic. In this example, processor 1004 is connected to a bus 1002 or other communications medium.

Computing system 1000 can also include a main memory 1008, such as random access memory (RAM) or other dynamic memory, for storing information and instructions to be executed by processor 1004. Main memory 1008 also may be used for storing temporary variables or other intermediate information during execution of instructions to be executed by processor 1004. Computing system 1000 may likewise include a read only memory (“ROM”) or other static storage device coupled to bus 1002 for storing static information and instructions for processor 1004.

The computing system 1000 may also include information storage system 1010, which may include, for example, a media drive 1012 and a removable storage interface 1020. The media drive 1012 may include a drive or other mechanism to support fixed or removable storage media, such as a hard disk drive, a floppy disk drive, a magnetic tape drive, an optical disk drive, a CD or DVD drive (R or RW), or other removable or fixed media drive. Storage media 1018, may include, for example, a hard disk, floppy disk, magnetic tape, optical disk, CD or DVD, or other fixed or removable medium that is read by and written to by media drive 1014. As these examples illustrate, the storage media 1018 may include a computer-readable storage medium having stored therein particular computer software or data.

In alternative embodiments, information storage system 1010 may include other similar components for allowing computer programs or other instructions or data to be loaded into computing system 1000. Such components may include, for example, a removable storage unit 1022 and an interface 1020, such as a program cartridge and cartridge interface, a removable memory (for example, a flash memory or other removable memory module) and memory slot, and other removable storage units 1022 and interfaces 1020 that allow software and data to be transferred from the removable storage unit 1018 to computing system 1000.

Computing system 1000 can also include a communications interface 1024. Communications interface 1024 can be used to allow software and data to be transferred between computing system 1000 and external devices. Examples of communications interface 1024 can include a modem, a network interface (such as an Ethernet or other NIC card), a communications port (such as for example, a USB port), a PCMCIA slot and card, etc. Software and data transferred via communications interface 1024 are in the form of signals which can be electronic, electromagnetic, optical or other signals capable of being received by communications interface 1024. These signals are provided to communications interface 1024 via a channel 1028. This channel 1028 may carry signals and may be implemented using a wireless medium, wire or cable, fiber optics, or other communications medium. Some examples of a channel include a phone line, a cellular phone link, an RF link, a network interface, a local or wide area network, and other communications channels.

In this document, the terms “computer program product,” “computer-readable medium” and the like may be used generally to refer to media such as, for example, memory 1008, storage device 1018, or storage unit 1022. These and other forms of computer-readable media may store one or more instructions for use by processor 1004, to cause the processor to perform specified operations. Such instructions, generally referred to as “computer program code” (which may be grouped in the form of computer programs or other groupings), when executed, enable the computing system 1000 to perform functions of embodiments of the present invention. Note that the code may directly cause the processor to perform specified operations, be compiled to do so, and/or be combined with other software, hardware, and/or firmware elements (e.g., libraries for performing standard functions) to do so.

In an embodiment where the elements are implemented using software, the software may be stored in a computer-readable medium and loaded into computing system 1000 using, for example, removable storage drive 1014, drive 1012 or communications interface 1024. The control logic (in this example, software instructions or computer program code), when executed by the processor 1004, causes the processor 1004 to perform the functions of the invention as described herein.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or method steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A method for determining access to priority traffic flows at an access gateway (AGW) according to associated quality of service (QoS) priorities between user equipment (UE) and the access gateway (AGW), the method comprising:
receiving, from a network element, at least one uplink filter parameter;
receiving a message using a traffic flow, from a user equipment (UE), including an indicator of an actual priority at an access point (AP), wherein the actual priority is determined at the UE according to a message characteristic and the at least one uplink filter parameters, and is associated with the used traffic flow;
using the at least one uplink filter parameter to determine an expected priority of the message; and
determining access based on comparing the expected priority and the actual priority of the message.

2. The method of claim 1, wherein the network element is a policy server.

3. The method of claim 1, wherein the at least one uplink filter parameter is a member of the group consisting of: source IP address, source port, destination IP address, destination port, and protocol identification.

4. The method of claim 1, wherein the expected priority matches the actual priority.

5. The method of claim 4, wherein access is allowed to a traffic flow associated with the actual priority.

6. The method of claim 1, wherein the expected priority does not match the actual priority.

7. The method of claim 6, wherein access is blocked from a traffic flow associated with the actual priority.

8. The method of claim 6, wherein access is reduced from a traffic flow associated with the actual priority.

9. The method of claim 1, wherein the receiving from a network element at least one uplink filter parameter is based on a non-access network-specific signaling.

10. The method of claim 9, wherein non-access network-specific signaling is session initiation protocol (SIP).

11. The method of claim 1, wherein the expected priority is a differentiated service priority.

12. The method of claim 1, wherein the actual priority is a differentiated service priority.

13. An access gateway (AGW) to affect the passage of transmitted messages over traffic priority flow according to associated quality of service (QoS), the access gateway comprising logic for:
receiving, from a network element, at least one uplink filter parameter;
receiving a message using a traffic flow, from a user equipment (UE), including an indicator of an actual priority at an access point (AP), wherein the actual priority is determined at the UE according to a message characteristic and the at least one uplink filter parameters, and is associated with the used traffic flow;
using the at least one uplink filter parameter to determine an expected priority of the message; and
determining access based on comparing the expected priority and the actual priority of the message.

14. The AGW of claim 13, wherein the network element is a policy server.

15. The AGW of claim 13, wherein the at least one uplink filter parameter is a member of the group consisting of: source IP address, source port, destination IP address, destination port, and protocol identification.

16. The AGW of claim 13, wherein the expected priority matches the actual priority.

17. The AGW of claim 16, wherein access is allowed to a traffic flow associated with the actual priority.

18. The AGW of claim 13, wherein the expected priority does not match the actual priority.

19. The AGW of claim 18, wherein access is blocked from a traffic flow associated with the actual priority.

20. The AGW of claim 18, wherein access is reduced from a traffic flow associated with the actual priority.

21. The AGW of claim 13, wherein the receiving from a network element at least one uplink filter parameter is based on a non-access network-specific signaling.

22. The AGW of claim 21, wherein non-access network-specific signaling is session initiation protocol (SIP).

23. The AGW of claim 13, wherein the expected priority is a differentiated service priority.

24. The AGW of claim 13, wherein the actual priority is a differentiated service priority.

25. A computer-readable medium comprising instructions for providing a service to a wireless terminal, the instructions for causing performance of a method comprising:
receiving, from a network element, at least one uplink filter parameter;
receiving a message using a traffic flow, from a user equipment (UE), including an indicator of an actual priority at an access point (AP), wherein the actual priority is determined at the UE according to a message characteristic and the at least one uplink filter parameters, and is associated with the used traffic flow;
using the at least one uplink filter parameter to determine an expected priority of the message; and
determining access based on comparing the expected priority and the actual priority of the message.

26. The computer-readable medium of claim 25, wherein the network element is a policy server.

27. The computer-readable medium of claim 25, wherein the at least one uplink filter parameter is a member of the group consisting of: source IP address, source port, destination IP address, destination port, and protocol identification.

28. The computer-readable medium of claim 25, wherein the expected priority matches the actual priority.

29. The computer-readable medium of claim 28, wherein access is allowed to a traffic flow associated with the actual priority.

30. The computer-readable medium of claim 25, wherein the expected priority does not match the actual priority.

31. The computer-readable medium of claim 30, wherein access is blocked from a traffic flow associated with the actual priority.

32. The computer-readable medium of claim 30, wherein access is reduced from a traffic flow associated with the actual priority.

33. The computer-readable medium of claim 25, wherein the receiving from a network element at least one uplink filter parameter is based on a non-access network-specific signaling.

34. The computer-readable medium of claim 33, wherein non-access network-specific signaling is session initiation protocol (SIP).

35. The computer-readable medium of claim 25, wherein the expected priority is a differentiated service priority.

36. The computer-readable medium of claim 25, wherein the actual priority is a differentiated service priority.
